(19) United States
(12) Patent Application Publication
(10) Pub. No.: US 2016/0373244 A1
(43) Pub. Date: Dec. 22, 2016

(54) PHASE TRACKING FOR CLOCK AND DATA RECOVERY

(71) Applicant: LATTICE SEMICONDUCTOR CORPORATION, Portland, OR (US)

(72) Inventors: Xiaozhi Lin, Shanghai (CN); Fei Song, Shanghai (CN); Xiaofeng Wang, Shanghai (CN); Zhiyuan Shen, Shanghai (CN); Baoli Tong, Shanghai (CN)

(21) Appl. No.: 14/917,556

(22) PCT Filed: Feb. 27, 2015
(86) PCT No.: PCT/CN2015/073353

§ 371 Date: Mar. 8, 2016

(51) Int. Cl. H04L 7/033; H03L 7/093; H03L 7/099; H03L 7/08

(52) U.S. Cl. CPC H04L 7/0331; H03L 7/0807; H03L 7/093; H03L 7/099; H04L 7/0087

(57) ABSTRACT

Clock and data recovery (CDR) systems for aligning a local clock signal to an incoming data signal to extract correct timing information from the incoming data signal are provided. A phase detector receives the local clock signal and the incoming data signal and generates an output phase error signal to indicate whether the local clock signal is leading or lagging the incoming data signal. The phase detector includes a bang-bang phase detector and a phase difference con roller. The output phase error signal is suitable for aligning the local clock signal to the incoming data signal.

### BACKGROUND

### 1. Field of the Disclosure

This disclosure pertains in general to clock and data recovery, and more specifically to phase tracking for clock and data recovery.

### 2. Description of the Related Art

Clock and data recovery (CDR) systems are used to recover the clock and data from a received signal. Some CDR systems include a bang-bang phase detector (BBPD) for identifying whether a local clock signal is leading or lagging the received data signal, in order to align the local clock signal with the received signal. However, a conventional BBPD can only correctly indicate the phase error when the local clock signal is within 0-0.5 unit intervals (UIs) of the received signal. For example, when the local clock signal and the incoming data signal are separated by 0.5-1.0 UI, instead of determining the phase error relative to the desired clock edge, a BBPD will determine the phase error relative to the next clock edge or relative to the former clock edge. If this phase error is used to synchronize the local clock signal, the local clock signal's phase will be adjusted incorrectly. As a result, the tracking range for a CDR's local clock is restricted because the BBPD is restricted to stay within 0-0.5 UIs of the received signal. This, in turn, can limit the operating frequency and data rate of the data communication system as a whole.

Therefore, an improved CDR circuit is needed to increase the data rate and expand the operating frequency of data communication systems.

### SUMMARY

Embodiments of the present disclosure are related to clock and data recovery (CDR) systems for aligning a local clock signal to an incoming data signal to extract correct timing information from the incoming data signal. A phase detector receives the local clock signal and the incoming data signal and generates an output phase error signal to indicate whether the local clock signal is leading or lagging the incoming data signal. The output phase error signal is suitable for aligning the local clock signal to the incoming data signal.

In one aspect, a phase detector includes a bang-bang phase detector (BBPD) and a phase difference controller. The BBPD receives the incoming data signal and the input data signal and outputs an interim phase error signal. The phase difference controller receives the interim phase error signal from the BBPD and outputs an output phase error signal. The output phase error signal includes a phase up signal and a phase down signal. The phase up signal or the phase down signal, when asserted, indicates the local clock signal leads or lags the incoming data signal, respectively. The phase difference controller includes a phase error interval detector and a polarity controller. The phase error interval detector detects whether the local clock signal is within 0.5-1.0 UI of the incoming data signal and outputs a polarity control signal. A unit interval (UI) is the period of the data signal. The polarity controller, according to the polarity control signal, reverses the polarity of the interim phase error signal when the local clock signal is detected to be within 0.5-1.0 UI of the incoming data signal.

The phase error interval detector detects when the local clock signal moves outside the 0-0.5 UI interval and into the 0.5-1.0 UI interval of the incoming data signal. In one implementation, the phase error interval detector includes a boundary detection module and a phase error state machine. The boundary detection module identifies whether the phase error is in a vicinity of the +0.5 UI or −0.5 UI and provides this to the phase error state machine. In one embodiment, the boundary detection module identifies the 0.5 UI boundary by capturing two samples of the incoming data signal in addition to the three samples captured by the BBPD in each time period. One of the additional samples is captured between the first data sample and the transition sample captured by the BBPD and the other additional sample is captured between the transition sample and the second data sample captured by the BBPD. Based on the received 0.5 UI boundary information and the BBPD's output, the phase error state machine determines whether the local clock signal is within 0.5-1.0 UI of the incoming data signal.

In another implementation, the phase error interval detector includes a cycle slip state machine. The cycle slip state machine detects a cycle slip of the BBPD and outputs a polarity control signal to reverse the BBPD's output when a cycle slip is detected. The cycle slip detection module receives BBPD's consecutive output in a plurality of consecutive time periods. A cycle slip of the BBPD is detected when the polarity of the BBPD's output reverses via a state where the BBPD's output including a phase down signal and a phase up signal both of which are simultaneously asserted or un-asserted.

Other aspects include components, devices, systems, improvements, methods, processes, applications and other technologies related to the foregoing.

### BRIEF DESCRIPTION OF THE DRAWINGS

The teachings of the embodiments disclosed herein can be readily understood by considering the following detailed description in conjunction with the accompanying drawings.

FIG. 1 is a block diagram of a clock and data recovery (CDR) system for recovering transmitted data from a received data signal, according to one embodiment.

FIG. 2A is a block diagram illustrating an example phase detector, suitable for use in the CDR system of FIG. 1.

FIG. 2B are graphs of interim phase error signal, polarity control signal and output phase error signal, as a function of phase error, for the example phase detector of FIG. 2A.

FIG. 3A is a block diagram illustrating another example phase detector, suitable for use in the CDR system of FIG. 1.

FIG. 3B are timing diagrams illustrating waveforms from the phase detector of FIG. 3A.

FIG. 3C are graphs of various signals as a function of phase error, for the phase detector of FIG. 3A.

FIG. 3D is a state diagram for the phase detector of FIG. 3A.

FIG. 4A is a block diagram illustrating another example phase detector, suitable for use in the CDR system of FIG. 1.

FIG. 4B is a timing diagram illustrating waveforms from the phase detector of FIG. 4A, when the local clock frequency is higher than the data rate.

FIG. 4C is a timing diagram illustrating waveforms from the phase detector of FIG. 4A, when the local clock frequency is lower than the data rate.

FIG. 4D is a state diagram for the phase detector of FIG. 4A.

### DETAILED DESCRIPTION

The Figures and the following description relate to various embodiments by way of illustration only. It should be noted that from the following discussion, alternative embodiments of the structures and methods disclosed herein will be readily recognized as viable alternatives that may be employed without departing from the principles discussed herein. Reference will now be made in detail to several embodiment examples of which are illustrated in the accompanying figures. It is noted that wherever practicable similar or like reference numbers may be used in the figures and may indicate similar or like functionality.

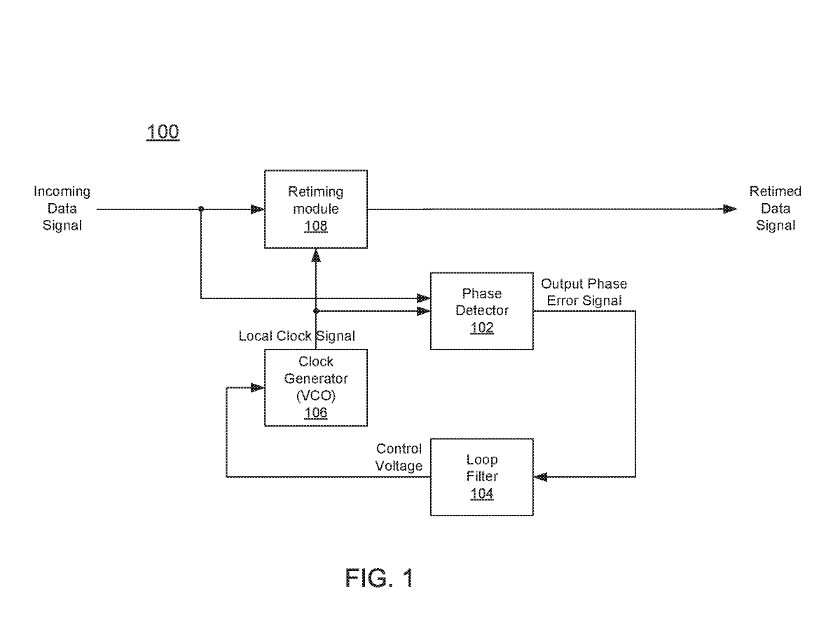

FIG. 1 is a block diagram of a clock and data recovery (CDR) system 100 for recovering and retiming transmitted data from a received data signal, according to one embodiment. The CDR system includes a retiming module 108 driven by a local clock signal, generated in this example by clock generator 106. The CDR system also includes a phase detector 102 and a loop filter 104 which form a feedback loop for the clock generator 106.

The retiming module 108 receives an incoming data signal, recovers the data from the incoming signal, and outputs the data retimed by the local clock signal. It does this by sampling the incoming data signal using the local clock signal. The retimed data is the transmitted data recovered from the incoming data signal, and the local clock signal ideally has the same frequency and is synchronized to the incoming data signal.

The incoming data signal may be transmitted by a transmitter of a source device to a receiver of a sink device, with the CDR system of FIG. 1 located in the receiver of the sink device. The source device may generate audiovisual data, and the sink device may receive and display the audiovisual data. Examples of a source device include mobile phones, digital video disc (DVD) players, blu-ray players, cable boxes, internet protocol television (IPTV) boxes, laptops, and integrated circuits (IC) within such devices. Examples of sink devices include televisions, LCD monitors, or ICs within such devices. Audiovisual data (e.g., video) is one example of an incoming data signal. Other examples of an incoming data signal include control data. In certain embodiments, the incoming data signal is transmitted from the source device to the sink device using a standard such as High-Definition Multimedia Interface (HDMI), Digital Visual Interface (DVI), Mobile High-Definition Link (MHL), DisplayPort, Peripheral Component Interconnect Express (PCIe), Universal Serial Bus (USB), etc. The clock frequency of an incoming data signal is usually in the multi-Gigahertz range. For example, the data rate of a USB 3.0 signal is about 5 Gbps and that of an HDMI 2.0 signal is about 6 Gbps.

The local clock signal ideally is synchronized to the incoming data signal. However, in the CDR system 100, the local clock signal is generated locally by the clock generator 106. The local clock signal is synchronized to the incoming data signal by a feedback loop which in this example includes phase detector 102 and loop filter 104.

The phase detector 102 determines the phase difference between the incoming data signal and the local clock signal. The phase detector 102 generates an output phase error signal representing the phase difference between the incoming data signal and the local clock signal. The phase error signal may indicate the other the local clock signal is leading or lagging the incoming data signal. In various embodiments, the output phase error signal may be a voltage signal. The loop filter 104 limits the amount of ripple appearing in the output phase error signal to generate a control voltage, applied as an input to the clock generator 106. The clock generator 106 may include a voltage-controlled oscillator (VCO) with variable frequency capability. The clock generator 106 adjusts the local clock signal according to the control voltage.

The loop filter 104 controls the frequency range of an incoming data signal to which a local clock signal can lock and how fast the local clock signal locks to the incoming data signal. The loop filter 104 determines the stability of the feedback loop. In some embodiments, the feedback loop may include a frequency changing element such as a frequency divider, a frequency multiplier, and/or a mixer such that the output of the clock generator 106 is locked to a reference signal which has a frequency that is a multiple or a sub-multiple of the frequency of the incoming data signal.

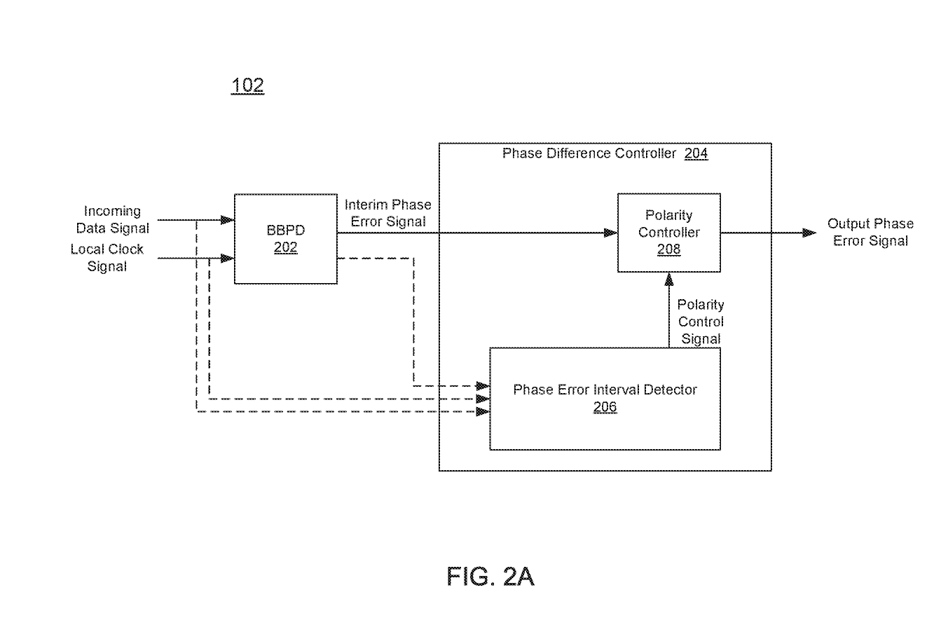

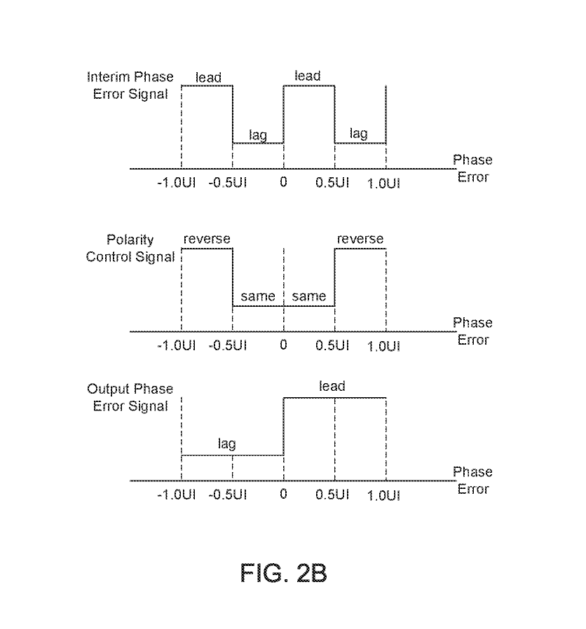

FIG. 2A is a block diagram illustrating an example phase detector 102, suitable for use in the CDR system of FIG. 1. The example phase detector 102 includes a bang-bang phase detector (BBPD) 202 and a phase difference controller 204 coupled to the BBPD 202. The phase difference controller 204 in this example includes a phase error interval detector 206 and a polarity controller 208.

The BBPD 202 receives the incoming data signal and the local clock signal as inputs and performs 2× oversampling of the incoming data signal using the local clock signal. That is, for each period of the incoming data signal, the data signal is sampled twice. For convenience, a period will also be referred to as a unit interval or UI. For example, the incoming data signal may be sampled at both the rising edges and falling edges of the local clock signal. Based on these samples, the BBPD 202 outputs an interim phase error signal to indicate whether the local clock signal is lagging or leading the incoming data signal.

The top graph of FIG. 2B illustrates operation of the BBPD 202. In these graphs, the phase error is the phase difference between the local clock signal and the incoming data signal. For a conventional BBPD, when the local clock signal is within 0-0.5 UI of the incoming data signal, the interim phase error signal (i.e., the BBPD's 202 output) correctly indicates whether the local clock signal is leading or lagging the incoming data signal. However, when the phase error is in the 0.5-1.0 UI range, the interim phase error signal misindicates whether the local clock signal is leading or lagging the incoming data signal. When the local clock signal is lagging the incoming data signal by 0.5-1.0 UI (far left of the graph), the interim phase error signal indicates that the local -lock signal is leading the incoming data signal when in fact it should indicate that the local clock signal is lagging. That is, the BBPD outputs the correct lead/lag indication only if the phase error is in the range [−0.5,+0.5] UI.

The phase difference controller 204 extends the operating range from [−0.5,+0.5] UI to at least [−1.0,−1.0] UI outputs an output phase error signal suitable for aligning the local clock signal to the incoming data signal. The phase difference controller 204 includes a phase error interval detector 206 and a polarity controller 208. The phase error interval detector 206 detects whether the local clock signal is within 0.5-1.0 UI of the incoming data signal, which is where the interim phase error signal misindicates the phase difference between the local clock signal and the incoming data signal, as illustrated in the top graph of FIG. 2B. When this is the case, the phase error interval detector 206 outputs a polarity control signal indicating that the lead/lag polarity should be reversed, as shown in the middle graph of FIG. 2B. The polarity controller 208 reverses the polar f the interim phase error signal based on the polarity control signal. The resulting output phase error signal is shown in the bottom graph of FIG. 2B.

In more detail, the phase error interval detector 206 can receive its input from various sources depending on its design. Typical input signals include the incoming data signal, the local clock signal, and one or more signals from the BBPD 202. These are shown as dashed lines in FIG. 2A. For instance, the BBPD 202 provides captured samples of the incoming data signal or the interim phase error signal to the phase error interval detector 206 as inputs. Based on these inputs, the phase error interval detector 206 detect whether the local clock signal is within 0.5-1.0 UI of the incoming data signal.

The phase error interval detector 206 outputs a polarity control signal to reverse the polarity of the interim phase error signal when the local clock signal is detected to be within 0.5-1.0 UI of the incoming data. signal. The polarity controller 208 controls the polarity of the interim phase error signal (i.e., lead vs lag) according to the polarity control signal. As show in the bottom graph of FIG. 2B, the polarity controller 208 reverses the polarity of the interim phase error signal when the local clock signal is within 0.5-1.0 UI of the incoming data signal. The polarity of the interim phase error signal is maintained when the local clock signal is within 0-0.5 UI of the incoming data signal. The output phase error signal therefore is suitable for aligning the local clock signal to the incoming data signal. The phase difference controller extends the operating range from [−0.5,+0.5] UI to [−1.0,−1.0] UI. In further embodiments, the phase difference controller can extend the operating range from [−0.5,+0.5] UI to [−∞, +∞] by detecting whether the local clock signal crosses other borders (e.g., the 1.0 UI border, the 1.5 UI border, etc.).

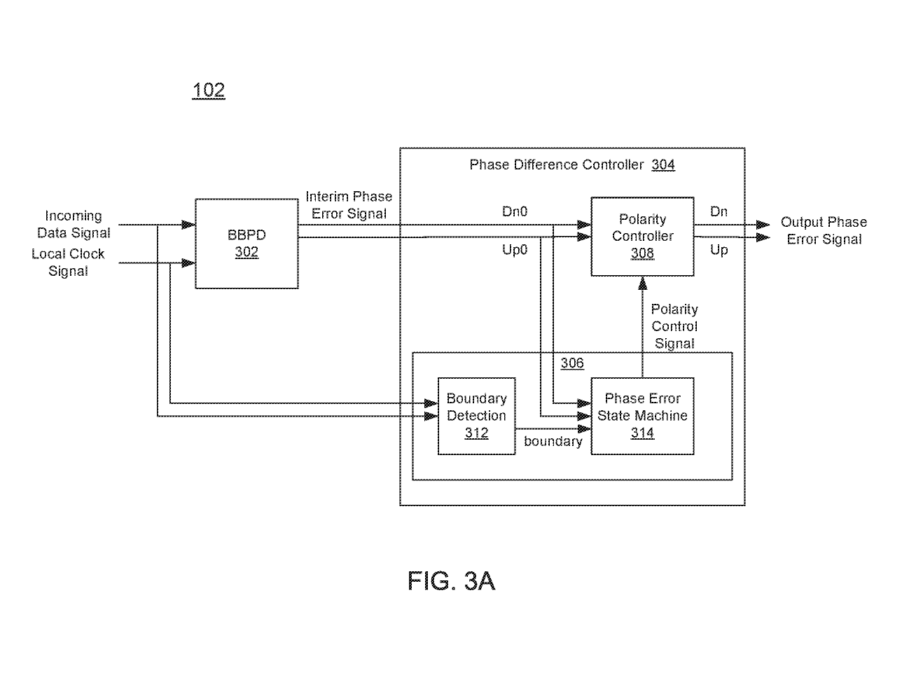

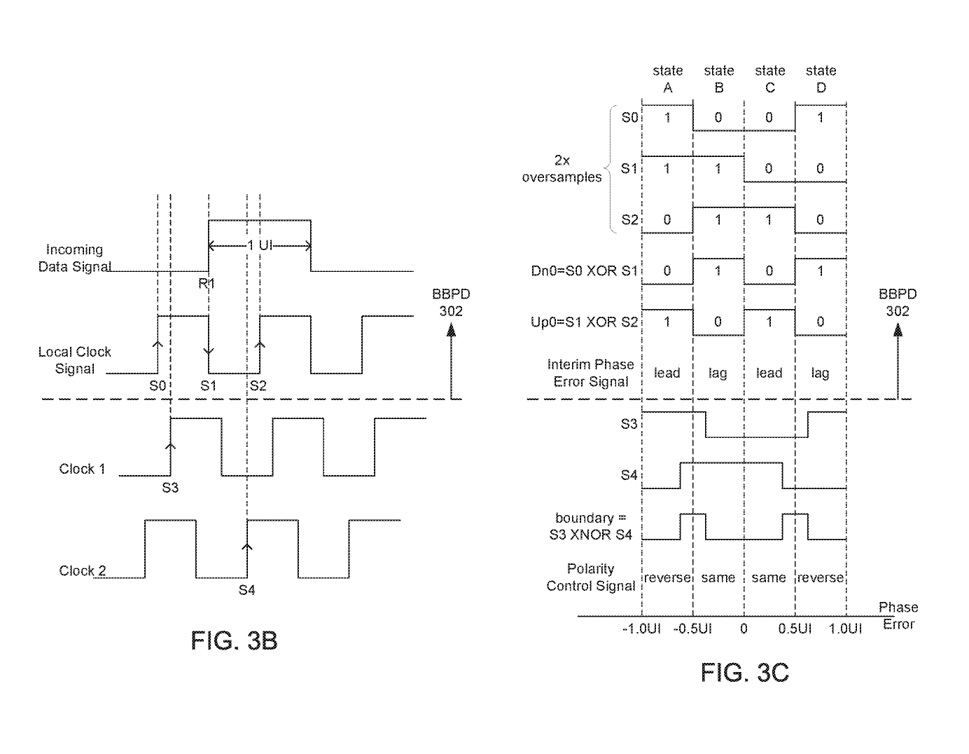

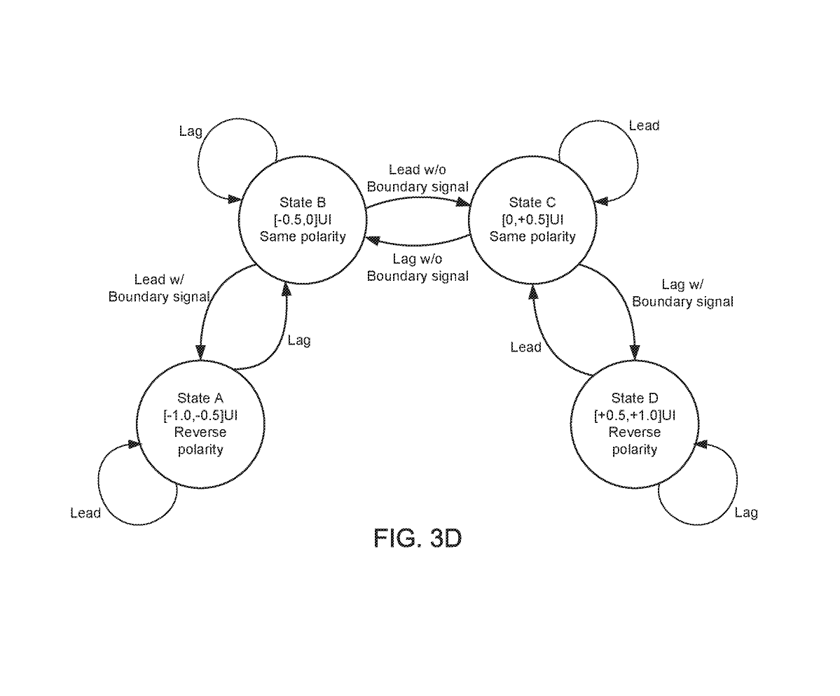

FIG. 3A is a block diagram illustrating another example phase detector 102, suitable for use in the CDR system of FIG. 1. FIG. 3B are timing diagrams illustrating waveforms, FIG. 3C are graphs of various signals as a function of phase error, and FIG. 3D is a state diagram for the phase detector of FIG. 3A. FIGS. 3A-3D are described in connection with each other. For purposes of this example, the phase error is assumed to stay within [−1.0,+1.0] UI. As illustrated in FIG. 3A, the phase detector 102 includes a BBPD 302 and a phase difference controller 304 coupled to the BBPD 302. The phase difference controller 304 includes a boundary detection module 312, a phase error state machine 314, and a polarity controller 308.

The BBPD 302 receives the incoming data signal and the local clock signal as inputs and performs 2× over-sampling of the incoming data signal using the local clock signal. FIG. 3B illustrates an example where the incoming data signal is alternating between 0 and 1 bits for purposes of illustration. The following example will be explained with respect to the transition from 0 to 1, but a similar result is achieved with respect to the transition from 1 to 0. To achieve 2× oversampling, the incoming data signal is sampled at the rising edges as well as at the falling edges of the local clock signal. For each time period, three samples include two consecutive data samples S0 and S2 captured at the rising edges of the local clock signal and a transition sample SI captured at the falling edge of the local clock signal. When the local clock signal is aligned with the incoming data signal, the transition sample S1 is aligned with a reference edge R1 of the incoming data signal. This sampling occurs as part of normal operation of the BBPD 302.

Referring to FIG. 3A, the BBPD 302 outputs an interim phase error signal that includes a phase down signal Dn0 and a phase up signal Up0. The phase down signal Dn0 is generated by XOR of the data sample SO and the transition sample S1. When asserted, the phase down signal Dn0 indicates the local clock signal is lagging the incoming data signal. The phase up signal Up0 is generated by XOR of the transition sample S1 and the data sample S2. When asserted, the phase up signal Up0 indicates the local clock signal is leading the incoming data signal.

This is illustrated in FIG. 3C. The first three rows of FIG. 3C show the 2× oversamples S0, S1 and S2 as a function of the phase error. Using S1 as an example and referring to FIG. 3B, as the phase error increases, this means the local clock signal moves to the left relative to the incoming data signal (i.e., moves ahead of the data signal) and the S1 sample will have a value of 0. As the phase error decreases, the local clock signal moves to the right (i.e., falls behind the data signal) and the S1 sample will have a value of 1.

The next two rows in FIG. 3C show the phase down signal Dn0 and the phase up signal Up0. When the local clock signal lags the incoming data signal by 0-0.5 UI (state B in FIG. 3C), S0=1 and S1=1 so the XOR of these two values yields Dn0=1. In addition, S1=1 and S2=1 so the XOR of these two values yields Up0=0. The BBPD's output includes an asserted phase down signal Dn0 at a high voltage level and an un-asserted phase up signal Up0 at a low voltage level, which properly indicates the local clock signal is lagging the incoming data signal. Similarly, when the local clock signal leads the incoming data signal by 0-0.5 UI (state C in FIG. 3C), the BBPD's output includes an un-asserted phase down signal Dn0 at a low voltage level and an asserted phase up signal Up0 signal at a high voltage level, which properly indicates the local clock signal is leading the incoming data signal.

However, when the local clock signal leads the incoming data signal by 0.5-1.0 UI (state D of FIG. 3C), the BBPD's output incorrectly indicates the local clock signal is lagging the incoming data signal. Similarly, when the local clock signal lags the incoming data signal by 0.5-1.0 UI (state A of FIG. 3C), the BBPD's output incorrectly indicates the local clock signal is leading the incoming data signal. The lead/lag states were derived in FIG. 3C using a transition from 0 to 1, but the same result is achieved for the transition from 1 to 0.

The phase difference controller 304 corrects these two situations by taking two additional samples S3 and S4, as shown in FIGS. 3B and 3C. Sample S3 is taken at some point between samples S0 and S1, and sample S4 is taken at some point between samples S1 and S2. In FIG. 3B, sample S3 is shown as clocked by the rising edge of clock 1. Clock 1 is a delayed version of the local clock signal. Referring to FIG. 3A, the phase difference controller 304 receives the incoming data signal and local clock signal. It delays the local clock signal and uses this delayed version to sample the incoming data signal, thus producing sample S3. Similarly, sample S4 is clocked by the rising edge of clock 2, which is an accelerated version of the local clock signal.

The boundary detection module 312 determines whether the phase error is in a boundary region around +/−0.5 UI. That is, whether the phase error is in a vicinity of +/−0.5 UI is determined. In FIG. 3C, this is achieved by taking the XNOR of S3 and S4. The boundary signal is asserted when the phase error s in a vicinity of +0.5 UI or −0.5 UI. This boundary signal is used to distinguish the ambiguous states A and D. For example, assume that the phase error was in state B (i.e., in the range [−0.5,0] UI) and the interim phase error signal was lag. If the interim phase error signal transitions from lag to lead, it can be determined whether the phase error is in state A or state C depending on whether the boundary at −0.5 UI was crossed. If the interim phase error signal transitioned from lag to lead without asserting the boundary signal, then the boundary at −0.5 UI was not crossed, the transition is from state B to state C and no polarity reversal is needed. However, if the interim phase error signal transitioned from lag to lead and there was an assertion of the boundary signal, then the transition is from state B to state A and a polarity reversal is needed.

The phase error state machine 314 determines the sequence of states as shown in FIG. 3D. The four states shown correspond to the states A-D in FIG. 3C. For example, state B corresponds to a phase error of [−0.5,0] UI and a polarity control signal indicating same polarity (i.e., no reversal). The transitions between states are driven by the interim phase error signal, which takes a value of Lead (Dn0=0 and Up0=1) or Lag (Dn0=1 and Up0=0), and the boundary signal. “w/ boundary signal” means that the boundary signal is asserted. The phase error state machine 314 outputs the corresponding polarity control signal, as shown in the last row of FIG. 3C. The polarity controller 308 reverses or does not reverse the polarity of the interim phase error signal according to the polarity control signal.

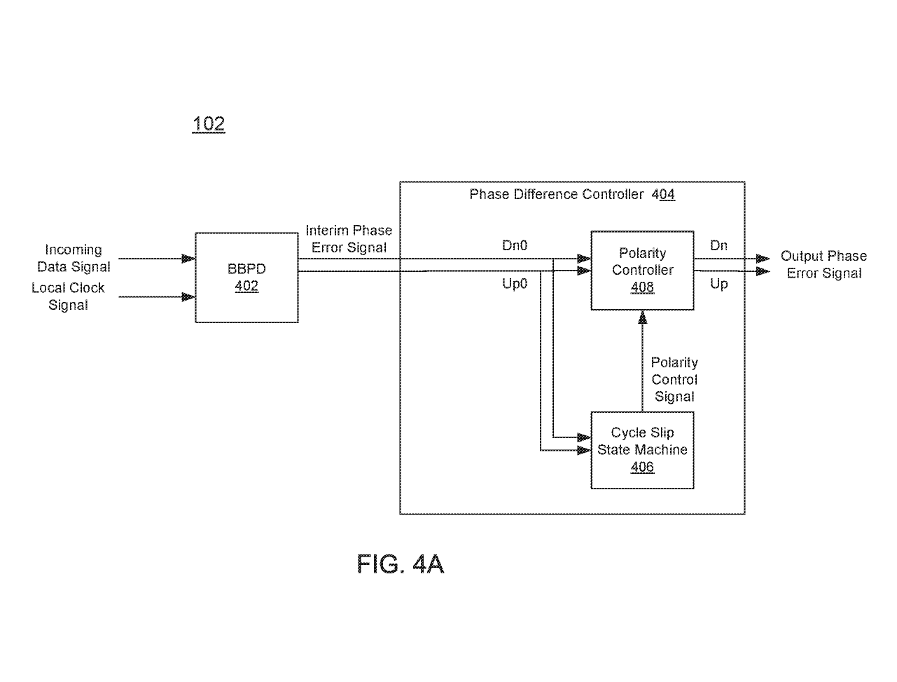

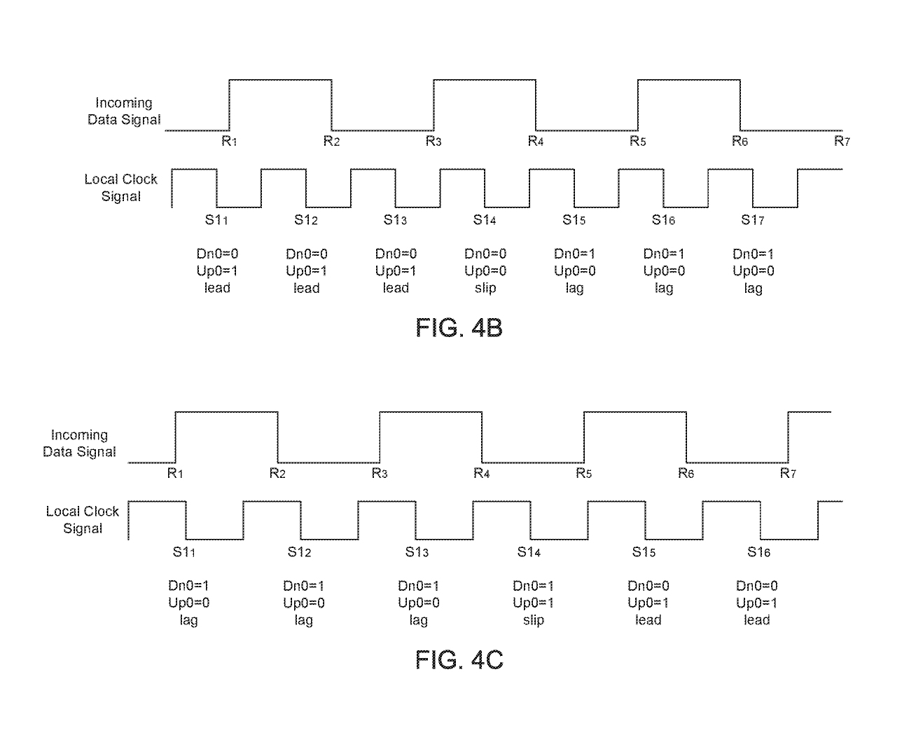

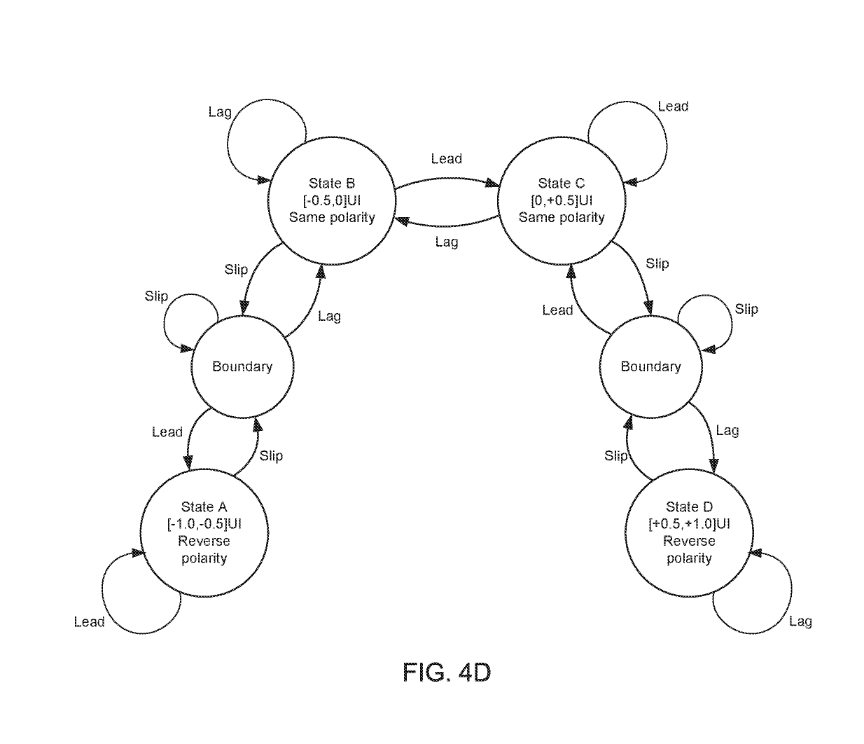

FIG. 4A is a block diagram illustrating another example phase detector 102, suitable for use in the CDR system of FIG. 1. FIGS. 4B and 4C illustrate waveforms, where the local clock frequency is higher than and lower than the data rate, respectively, FIG. 4D illustrates a state diagram for the example phase detector illustrated in FIG. 4A. FIGS. 4A-4D are described in connection with each other. For purposes of this example, the phase error is assumed to stay within [−1.0,+1.0] UI. As illustrated in FIG. 4A, the phase detector 102 includes a BBPD 402 and a phase difference controller 404 coupled to the BBPD 402. The phase difference controller 404 includes a cycle slip state machine 406 and a polarity controller 408.

As illustrated in FIG. 4A, the phase difference controller 404 receives the output of the BBPD 402 including a phase down signal Dn0 and a phase up signal Up0. The cycle slip state machine 406 detects cycle slip. Cycle slip occurs when the BBPD 402 aligns the local clock signal to an edge different from the reference edge of the incoming data signal. Detecting cycle slip is another way to detect the boundary crossing described in FIG. 3. The state machine 406 then outputs a corresponding polarity control signal, according to which the polarity controller 408 reverses or does not reverse the BBPD's 402 output.

FIGS. 4B and 4C illustrate cycle slip. In FIG. 4B, the local clock frequency is higher than the data rate of the incoming data signal. FIG. 4B shows several periods of the data signal alternating between 0 and 1 bits, FIG. 4B also shows the local clock signal. The edges R of the data signal correspond to the edges S1 ₙ of the local clock signal. If the two signals were synchronized, then each edge Rₙ would be aligned with the corresponding edge S1ₙ. In this example, edge S1₁ slightly leads the corresponding reference edge R₁ but is within 0-0.5 UI of the reference edge R₁. The BBPD's output is Dn0=0 and Up0=1, which indicates that the local clock signal is leading the data signal. Since the local clock, signal has a higher frequency than the data signal, in the next cycle the local clock signal will lead by even more. The local clock signal's edge S1₂ leads the corresponding reference edge R₂ of the incoming data signal, and next edge S1₃ also leads the reference edge R₃. For both of these, the BBPD's output is still Dn0=0 and Up0=1, which indicates that the local clock signal is leading the data signal.

However, as the phase lead continues to increase, cycle slip occurs. Local clock signal edges S1₅-S1₇ are leading their respective reference edges R₅-R₇ by more than 0.5 UI, so the BBPD outputs Dn0=1 and Up0=0, which incorrectly indicates that the local clock signal is lagging the data signal. This is because the BBPD's output indicates the edge S1₅ is lagging the closest reference edge R₄ rather than leading the correct reference edge R₅. Note that for local clock edge S1₄, the BBPD outputs an anomalous state with Dn0=0 and Up0=0. This will be referred to as a slip signal because it indicates the beginning of cycle slip.

As shown in FIG. 4C, a similar situation occurs when the local clock signals is slower than the incoming data signal. In this example, local clock signal edges S1₁-S1₃ are lagging their respective reference edges R₁-R₃ but by less than 0.5 UI. Accordingly, the BBPD's output of Dn0=1 and Up0=0 properly indicates that the local clock signal lags the incoming data signal. Because the local clock signal is a lower frequency, the lag increases with each passing cycle. Local clock signal edges S1₅-S1₆ are lagging their respective reference edges R₅-R₆ by more than 0.5 UI. As a result, the BBPD outputs Dn0=0 and Up0=1, which incorrectly indicates that the local clock signal is leading the data signal. This is because the BBPD determination is relative to the closest data edge. As in FIG. 4B, for local clock edge S1₄, the BBPD outputs an anomalous state with Dn0=1 and Up0=1.

If the incoming data signal toggles between 0 and 1, then the slip signals (Dn0=Up0=0 and Dn0=Up0=1) occur only when the phase error is crossing the +0.5 UI or −0.5 UI border. They do not occur when the phase error is transitioning between leading and lagging. As a result, the cycle slip state machine 406 can use this fact to distinguish the ambiguous states A and D where the phase error is 0.5-1.0 UI. Note that the slip signal (Dn0=Up0=0) may also occur if the incoming data signal is not toggling between 0 and 1. Consecutive 0's or consecutive 1's will produce the slip signal (Dn0=Up0=0). To account for this, the cycle slip state machine 406 may operate only when the incoming data signal is known to alternate between 0 and 1 or may use a training signal that alternates between 0 and 1. Alternately, additional samples may be captured in similar ways to the capturing samples S3 and S4 as described with reference to FIGS. 3B and 3C.

The state machine 406 operates according to the state diagram illustrated in FIG. 4D. The states A-D shown correspond to the states A-D in FIG. 3C. For example, state B corresponds to a phase error of [−0.5,0] UI and a polarity control signal indicating same polarity (i.e., no reversal). There are two additional states that are labelled “Boundary,” because they correspond to the +/−0.5 UI boundary. The transitions between states are driven by the interim phase error signal, which takes a value of Lead (Dn0=0 and Up0=1) or Lag (Dn0=1 and Up0=0) or Slip (Dn0=Up0=0 or Dn0=Up0=1).

The cycle slip state machine 406 outputs the corresponding polarity control signal, as shown in the state diagram of FIG. 4D. The polarity controller 408 reverses or does not reverse the polarity of the interim phase error signal according to the polarity control signal.

Upon reading this disclosure, those of skill in the art will appreciate still additional alternative designs. Thus, while particular embodiments and applications of the present disclosure have been illustrated and described, it is to be understood that the embodiments are not limited to the precise construction and components disclosed herein and that various modifications, changes and variations which will be apparent to those skilled in the art may be made in the arrangement, operation and details of the method and apparatus of the present disclosure disclosed herein without departing from the spirit and scope of the disclosure as defined in the appended claims.

What is claimed is:

1. A clock and data recovery device for aligning a local clock signal to an incoming data signal, the device comprising:
a bang-bang phase detector (BBPD) to receive the incoming data signal and the local clock signal and to perform 2× oversampling of the data signal using the local clock signal and further to generate an interim phase error signal based on three of the 2× oversamples, the interim phase error signal indicating whether the local clock signal leads or lags the input data signal if the local clock signal is within 0.0-0.5 UI of the input data signal, wherein 1 UI (unit interval) is a period of the input data signal;
a phase error interval detector to determine whether the local clock signal is within 0.5-1.0 UI of the input data signal; and
a polarity controller coupled to the BBPD and the phase error interval detector, to generate an output phase error signal by reversing a polarity of the interim phase error signal if the local clock signal is within 0.5-1.0 UI of the input data signal, wherein the output phase error signal is suitable for aligning the local clock signal to the data signal.

2. The clock and data recovery device of claim 1, wherein the output phase error signal comprises a phase down signal indicating whether the local clock signal is lagging the data signal and a phase up signal indicating whether the local clock signal is leading the data signal.

3. The clock and data recovery device of claim 1, wherein the three 2× oversamples are three consecutive 2× oversamples S0, S1 and S2, wherein S1 is aligned with a reference edge of the data signal when the local clock signal is aligned with the data signal.

4. The clock and data recovery device of claim 3, wherein the interim phase error signal comprises a phase down signal indicating whether the local clock signal is lagging the data signal and a phase up signal indicating whether the local clock signal is leading the data signal; and each of the phase up and phase down signals is generated by XOR of two of the three 2× oversamples.

5. The clock and data recovery device of claim 3, wherein the phase error interval detector receives the three 2× oversamples S0, S1 and S2, a fourth sample captured between S0 and S1 and a fifth sample captured between S1 and S2; and the phase error interval detector determines whether the local clock signal is within 0.5-1.0 UI of the input data signal based on these five samples.

6. The clock and data recovery device of claim 3, wherein the phase error interval detector receives phase up and phase down signals for a current time period and for one or more previous time periods; and the phase error interval detector determines Whether the local clock signal is within 0.5-1.0 UI of the input data signal based on these phase up and phase down signals.

7. The clock and data recovery device of claim 1, wherein the phase error interval detector is further to determine whether a phase difference between the local clock signal and the data signal is increasing or decreasing, and to determine whether the local clock signal is within 0.5-1.0 UI of the input data signal based on whether the phase difference is increasing or decreasing.

8. The clock and data recovery device of claim 7, wherein the phase error interval detector includes a state machine to track 0.5 UI interval, wherein a current 0.5 UI interval depends on a prior 0.5 UI interval and whether the phase difference is increasing or decreasing.

9. The clock and data recovery device of claim 1, wherein the phase error interval detector is further to detect a cycle slip of the BBPD.

10. The clock and data recovery device of claim 9, wherein the interim phase error signal comprises a phase down signal indicating whether the local clock signal is lagging the data signal and a phase up signal indicating whether the local clock signal is leading the data signal, and the cycle slip is detected when a polarity of the interim phase error signal is reversed after a state when both the phase up and phase down signals are simultaneously asserted or un-asserted.

11. The clock and data recovery device of claim 1, wherein the device has an operating range of at least [−1.0,+1.0] UI, over which the device aligns the local clock signal to the incoming data signal.

12. The clock and data recovery device of claim 1, wherein the device has an operating range of at least [−2.0,+2.0] UI, over which the device aligns the local clock signal to the incoming data signal.

13. A system comprising the clock and data recovery device of claim 1, the system further comprising:
a clock generator that generates the local clock signal; and
a feedback loop from the polarity controller to the clock generator, the feedback loop adjusting the clock generator according to the output phase error signal to align the local clock signal to the data signal.

14. The system of claim 13, wherein the feedback loop comprises a loop filter and the clock generator comprises a voltage controlled oscillator.

15. The system of claim 13, further comprising a retimer to sample the incoming data signal according to the local clock signal.

16. The system of claim 13, wherein the feedback loop operates only when the incoming data signal is toggling between 0 and 1.

17. The system of claim 13, wherein the feedback loop operates when the incoming data signal is a training signal that toggles between 0 and 1.

18. The system of claim 13, wherein the three 2× oversamples are three consecutive 2× oversamples S0, S1 and S2, wherein S1 is aligned with a reference edge of the data signal when the local clock signal is aligned with the data signal.

19. The system of claim 13, wherein the clock and data recovery device has an operating range of at least [−1.0,+1.0] UI, over which the device aligns the local clock signal to the incoming data signal.

20. The system of claim 13, wherein the clock and data recovery device has an operating range of at least [−2.0,+2.0] UI, over which the device aligns the local clock signal to the incoming data signal.
